(19) United States
(12) Patent Application Publication
(10) Pub. No.: US 2025/0115785 A1
(43) Pub. Date: Apr. 10, 2025

(54) SLURRY COMPOSITION FOR CHEMICAL MECHANICAL METAL POLISHING AND POLISHING METHOD USING THE SAME

(71) Applicant: SAMSUNG ELECTRONICS CO., LTD., Suwon-si (KR)

(72) Inventors: Wonki HUR, Suwon-si (KR); Seokjoo KIM, Seongnam-si (KR); Daehoon YANG, Seongnam-si (KR); Sanghyun PARK, Suwon-si (KR); Gayoung KIM, Suwon-si (KR); Sangkyun KIM, Suwon-si (KR); Inkwon KIM, Suwon-si (KR); Eunho SONG, Suwon-si (KR); Jaekwang CHOI, Suwon-si (KR)

(73) Assignees: SAMSUNG ELECTRONICS CO., LTD., Suwon-si (KR); SOULBRAIN CO., LTD., Seongnam-si (KR)

(21) Appl. No.: 18/771,727

(22) Filed: Jul. 12, 2024

(30) Foreign Application Priority Data
Oct. 6, 2023 (KR) 10-2023-0133409

(51) Int. Cl. C09G 1/02; B24B 37/04; C09K 3/14; C09K 15/30; H01L 21/321

(52) U.S. Cl. CPC C09G 1/02; B24B 37/044; C09K 3/1436; C09K 15/30; H01L 21/3212

(57) ABSTRACT

A slurry composition for chemical mechanical metal polishing includes a corrosion inhibitor, abrasive particles, an oxidizing agent, and a solvent. The corrosion inhibitor includes a C2 to C30 aliphatic heterocyclic compound including at least one nitrogen atom in the ring and at least one functional group selected from a halogen, an amine group, a cyclic amine group, a nitro group, an amide group, a carboxyl group, a hydroxy group, a thiol group, an alkoxy group, a C10 to C30 alkyl group, or an ester group; or a C2 to C30 aromatic heterocyclic compound including at least one nitrogen atom in the ring and at least one functional group selected from a halogen, an amine group, a cyclic amine group, a nitro group, an amide group, a carboxyl group, a hydroxy group, a thiol group, an alkoxy group, a C10 to C30 alkyl group, and an ester group; or a combination thereof.

### CROSS-REFERENCE TO RELATED APPLICATION

This application claims priority to and the benefit of Korean Patent Application No. 10-2023-0133409 filed in the Korean Intellectual Property Office on Oct. 6, 2023, the disclosure of which is incorporated herein by reference in its entirety.

### BACKGROUND

### 1. Field

This disclosure relates to a slurry composition for chemical mechanical metal polishing and a polishing method using the same.

### 2. Description of the Related Art

The semiconductor manufacturing process includes a process of forming an insulation layer and a conductive layer on a substrate, a process of planarizing the surface after forming the layer, and a process of forming a certain shape by etching the formed insulation layer and conductive layer. In the semiconductor manufacturing process, a conductive layer can be used to form an electrode or wiring, or to form a contact plug that electrically connects two conductive structures.

Processes for realizing film planarization include, for example, etch back, reflow, and chemical mechanical polishing (CMP), but the chemical mechanical polishing process is the most widely used method for wide-area planarization and highly integrated circuits. This is because not only is wide-area planarization possible only by a chemical mechanical polishing process, but also the chemical mechanical polishing process is the best in terms of satisfaction with flatness.

The chemical mechanical polishing process refers to a process of mounting a semiconductor substrate to be polished, providing a slurry composition including an abrasive between the semiconductor substrate and a polishing pad, rotating the semiconductor substrate while in contact with the polishing pad, pressurizing and planarizing the surface of the semiconductor substrate by rotation. That is, the surface of the semiconductor substrate may include mechanically polishing by mechanically rubbing the surface protrusions of the polishing pad and the abrasive included in the polishing slurry with the surface of the semiconductor substrate, while simultaneously chemically removing the surface of the semiconductor substrate by chemically reacting the chemical components included in the slurry composition with the surface of the semiconductor substrate.

Meanwhile, to improve the performance of semiconductor devices, the width of wiring has been continuously reduced, and at the same time, low-resistance conductive materials (metals) have been continuously requested. However, until now, a resistance of metallic materials (bulk metal) has been generally related to a resistance of actual wiring (contact metal), but as a line width decreases, the line width decreases by the grain size, and a mean free path becomes a new factor in determining resistance.

Accordingly, a target resistance cannot be secured with the existing contact material, tungsten, and the introduction of molybdenum is required.

Molybdenum can be used in a variety of industrial applications, including microelectronic devices (e.g., fabrication of interconnects, photo masks, and semiconductor devices), and in order to provide a substrate with suitable surface properties, some of the molybdenum needs to be removed.

### SUMMARY

One aspect of the present disclosure is to implement a slurry composition for chemical mechanical metal polishing that can increase the polishing rate while reducing etching of molybdenum/tungsten.

Another aspect of the present disclosure is to implement a polishing method that not only simplifies a process by unifying two steps in a polishing process, but also improves a polishing rate of molybdenum/tungsten by increasing a selectivity ratio of a molybdenum/tungsten removal rate to a removal rate of silicon nitride.

A slurry composition for chemical mechanical metal polishing according to one aspect includes a corrosion inhibitor, abrasive particles, an oxidizing agent, and a solvent, wherein the corrosion inhibitor includes a C2 to C30 aliphatic heterocyclic compound having a ring with at least one nitrogen atom and at least one functional group selected from a halogen, an amine group, a cyclic amine group, a nitro group, an amide group, a carboxyl group, a hydroxy group, a thiol group, an alkoxy group, a C10 to C30 alkyl group, or an ester group; or a C2 to C30 aromatic heterocyclic compound having a ring with at least one nitrogen atom and at least one functional group selected from a halogen, an amine group, a cyclic amine group, a nitro group, an amide group, a carboxyl group, a hydroxy group, a thiol group, an alkoxy group, a C10 to C30 alkyl group, and an ester group; or a combination thereof.

A polishing method according to another aspect includes arranging a polishing pad to face a surface of a substrate, wherein the substrate includes a layer having at least one of molybdenum (Mo), tungsten (W), or an alloy thereof; supplying the aforementioned slurry composition between the substrate and the polishing pad; and polishing the substrate by bringing the surface of the substrate into contact with the polishing pad.

A slurry composition for chemical mechanical polishing according to one aspect improves a polishing rate of molybdenum/tungsten while suppressing corrosion of molybdenum/tungsten by chemical etching. Since the upper portion composed of molybdenum (Mo), tungsten (W) and/or their alloys is polished, and the lower portion containing silicon oxide and molybdenum, tungsten and/or their alloys can be polished continuously without stopping, which is advantageous in the process.

The polishing method according to another aspect can increase a removal rate of molybdenum/tungsten and silicon oxide while increasing the selectivity to the removal rate of silicon nitride.

### BRIEF DESCRIPTION OF THE DRAWINGS

FIG. 1 is a diagram showing that, unlike the conventional polishing method, the polishing method according to one aspect can be implemented in a process shortened to two steps.

FIG. 2 is a diagram showing that the conventional polishing method proceeds through a three-step process.

FIG. 3 is a perspective view conceptually showing a polishing device capable of performing chemical mechanical polishing.

FIG. 4 is a graph showing molybdenum removal rate and corrosion rate (etch rate) by chemical etching.

### DETAILED DESCRIPTION

The present invention will be described more fully hereinafter with reference to the accompanying drawings, in which embodiments of the invention are shown. As those skilled in the art would realize, the described embodiments may be modified in various different ways, all without departing from the scope of the present invention.

The drawings and description are to be regarded as illustrative in nature and not restrictive. Like reference numerals designate like elements throughout the specification.

The size and thickness of each constituent element as shown in the drawings may be randomly indicated for better understanding and ease of description, and this disclosure is not necessarily limited to as shown. In the drawings, the thickness of layers, films, panels, regions, etc., may be exaggerated for clarity. In addition, in the drawings, for better understanding and ease of description, the thickness of some layers and areas may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

As used herein, when a definition is not otherwise provided, “substituted” refers to replacement of hydrogen by a substituent selected from a halogen atom (F, Cl, Br, or I), a hydroxy group, a C1 to C20 alkoxy group, a nitro group, a cyano group, an amine group, an imino group, an azido group, an amidino group, a hydrazino group, a hydrazono a group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

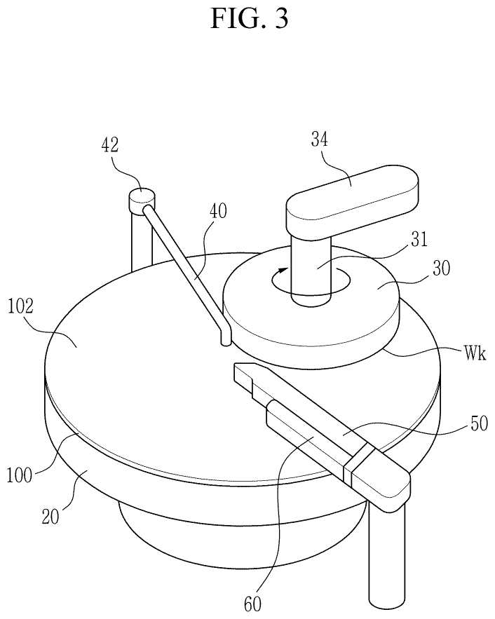

FIG. 3 is a perspective view conceptually showing a polishing device capable of performing chemical mechanical polishing.

Referring to FIG. 3, the polishing device uses a polishing pad 100 having a polishing surface 102 and is configured to polish a substrate Wk such as a semiconductor wafer as a polishing object. As shown, the polishing device includes a polishing table 20 that supports the polishing pad 100, and a top ring (substrate holding portion) 30 that holds the substrate Wk and is pressed against the polishing pad 100. Additionally, the polishing device is provided with a polishing liquid supply nozzle (polishing liquid supply unit) 40 that supplies polishing liquid (slurry) to the polishing pad 100.

The polishing table 20 is formed in a disk shape and is rotatable with its central axis as the rotation axis. A polishing pad 100 is installed on the polishing table 20 by attachment or the like. The surface of the polishing pad 100 forms a polishing surface 102. The polishing pad 100 rotates integrally with the polishing table 20 when the polishing table 20 is rotated by a motor (not shown).

The top ring 30 holds the substrate Wk as a polishing object on its lower surface by vacuum suction or the like. The top ring 30 is configured to rotate together with the substrate Wk by power from a motor (not shown). The upper portion of the top ring 30 is connected to the support arm 34 through a shaft 31. The top ring 30 can be moved up and down by an air cylinder (not shown), and its distance from the polishing table 20 can be adjusted. As a result, the top ring 30 can press the held substrate Wk against the surface (polishing surface) 102 of the polishing pad 100. Additionally, the support arm 34 is configured to be able to swing by a motor (not shown), and moves the top ring 30 in a direction parallel to the polishing surface 102. In this embodiment, the top ring 30 is configured to be movable between a receiving position for the substrate Wk (not shown) and a position above the polishing pad 100, and is configured so that the pressing position of the substrate Wk with respect to the polishing pad 100 can be changed. Hereinafter, the pushing position (holding position) of the substrate Wk by the top ring 30 is also referred to as a “polishing area.”

The polishing liquid supply nozzle 40 is installed above the polishing table 20 and supplies polishing liquid (slurry) to the polishing pad 100 supported on the polishing table 20. The polishing liquid supply nozzle 40 is supported by the shaft 42. The shaft 42 is configured to be swingable by a motor (not shown), and the polishing liquid supply nozzle 40 can change the dropping position of the polishing liquid during polishing.

Additionally, the polishing device also includes a control unit that controls the overall operation of the polishing device. The control unit may be configured as a microcomputer that includes a CPU, memory, etc. and realizes desired functions using software, or may be configured as a hardware circuit that performs dedicated arithmetic processing.

In the polishing device, the substrate Wk is polished as follows. First, the top ring 30 holding the substrate Wk on the lower surface is rotated, and the polishing pad 100 is rotated. In this state, the polishing liquid is supplied to the polishing surface 102 of the polishing pad 100 from the polishing liquid supply nozzle 40, and the substrate Wk held by the top ring 30 is pressed against the polishing surface 102. As a result, the substrate Wk and the polishing pad 100 move relative to each other while the surface of the substrate Wk is in contact with the polishing pad 100 in the presence of the slurry. In this way, the substrate Wk is polished.

As shown in FIG. 3, the polishing device further includes a polishing liquid removal unit 50 and a temperature control unit 60.

Example embodiments provide a slurry composition for chemical mechanical metal polishing that can be used in the polishing device 100.

The slurry composition for chemical mechanical metal polishing includes a corrosion inhibitor, abrasive particles, an oxidizing agent, and a solvent, wherein the corrosion inhibitor includes a C2 to C30 aliphatic heterocyclic compound including at least one nitrogen atom in the ring and at least one functional group selected from a halogen, an amine group, a cyclic amine group, a nitro group, an amide group, a carboxyl group, a hydroxy group, a thiol group, an alkoxy group, a C10 to C30 alkyl group, or an ester group; or a C2 to C30 aromatic heterocyclic compound including at least one nitrogen atom in the ring and at least one functional group selected from a halogen, an amine group, a cyclic amine group, a nitro group, an amide group, a carboxyl group, a hydroxy group, a thiol group, an alkoxy group, a C10 to C30 alkyl group, or an ester group; or a combination thereof.

When the oxidizing agent in the slurry composition for chemical mechanical metal polishing oxidizes the metal surface and creates an oxide film, melting (oxidation) occurs in part of the metal, and as a result, partial recess occurs, which adversely affects planarization and has a fatal impact on semiconductor manufacturing yield.

The corrosion inhibitor according to the present disclosure can implement a mechanism to protect the surface of the oxide film and prevent recess due to additional oxidation before the abrasive particles remove the oxide film. The corrosion inhibitor may have multiple functional groups or bulky structures to protect the surface.

The corrosion inhibitor includes a C2 to C30 aliphatic heterocyclic compound including at least one nitrogen atom in the ring and at least one functional group selected from a halogen, an amine group, a cyclic amine group, a nitro group, an amide group, a carboxyl group, a hydroxy group, a thiol group, an alkoxy group, a C10 to C30 alkyl group, or an ester group; or a C2 to C30 aromatic heterocyclic compound including at least one nitrogen atom in the ring and at least one functional group selected from a halogen, an amine group, a cyclic amine group, a nitro group, an amide group, a carboxyl group, a hydroxy group, a thiol group, an alkoxy group, a C10 to C30 alkyl group, or an ester group; or a combination thereof.

As an example, the corrosion inhibitor may include one or more of the following: diazepane including at least one functional group selected from a halogen, an amine group, a cyclic amine group, a nitro group, an amide group, a carboxyl group, a hydroxy group, a thiol group, an alkoxy group, a C10 to C30 alkyl group, or an ester group; pyridine including at least one functional group selected from a halogen, an amine group, a cyclic amine group, a nitro group, an amide group, a carboxyl group, a hydroxy group, a thiol group, an alkoxy group, a C10 to C30 alkyl group, or an ester group; pyridinium including at least one functional group selected from a halogen, an amine group, a cyclic amine group, a nitro group, an amide group, a carboxyl group, a hydroxy group, a thiol group, an alkoxy group, a C10 to C30 alkyl group, or an ester group; imidazole including at least one functional group selected from a halogen, an amine group, a cyclic amine group, a nitro group, an amide group, a carboxyl group, a hydroxy group, a thiol group, an alkoxy group, a C10 to C30 alkyl group, or an ester group; imidazolium including at least one functional group selected from a halogen, an amine group, a cyclic amine group, a nitro group, an amide group, a carboxyl group, a hydroxy group, a thiol group, an alkoxy group, a C10 to C30 alkyl group, or an ester group; pyrazole including at least one functional group selected from a halogen, an amine group, a cyclic amine group, a nitro group, an amide group, a carboxyl group, a hydroxy group, a thiol group, an alkoxy group, a C10 to C30 alkyl group, or an ester group; pyrazolium including at least one functional group selected from a halogen, an amine group, a cyclic amine group, a nitro group, an amide group, a carboxyl group, a hydroxy group, a thiol group, an alkoxy group, a C10 to C30 alkyl group, or an ester group.

For example, the corrosion inhibitor may include 11-undecyl-1,4-diazepane; 1-decyl-3-[(2S)-1-methyl-2-pyrrolidinyl] pyridinium iodide; 1-dodecylpyridinium chloride; 2-heptadecylimidazole; 1-dodecyl-1H-imidazole; 4-amino-1-dodecyl-pyridinium chloride; 1-heptyl-1H-imidazol-2-amine; 4-benzyl-1H-imidazol-2-amine; 4-chloro-1H-pyrazole-3-carboxylic acid; 5-Isopropyl-1H-pyrazol-3-amine; 4-Isopropyl-1H-pyrazol-3-amine; 1-decyl-3-methylimidazolium chloride; 3-decyl-1,2-dimethyl-1H-imidazol-3-ium bromide; or a combination thereof.

The corrosion inhibitor may be selected from compounds listed in Group 1.

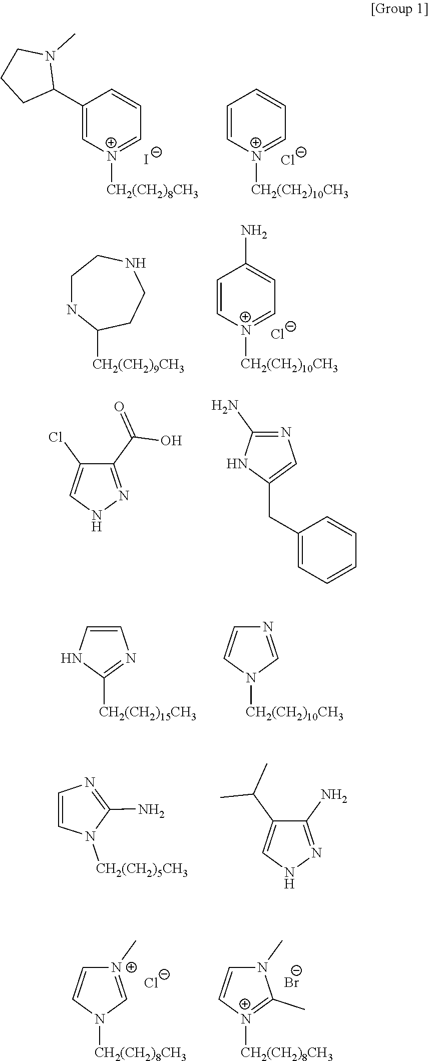

By including the corrosion inhibitor, it is possible to polish at a high polishing rate while mitigating loss due to melting of molybdenum oxide and/or tungsten oxide in a substrate including a metal, especially molybdenum and/or tungsten, so that layers including silicon oxide may also be polished through the same process without stopping, and thus a technology to shorten the polishing process may be implemented.

Additionally, the polishing method may implement a high selectivity for layer removal rate of the molybdenum-containing layer and/or tungsten-containing layer relative to a removal rate of a layer of a material other than the molybdenum-containing layer and/or the tungsten-containing layer (e.g., a silicon nitride-containing layer underlying the molybdenum-containing layer and/or the tungsten-containing layer).

An amount of corrosion inhibitor may vary in the range of about 0.001 wt % to about 10 wt %, about 0.005 wt % to about 10 wt %, about 0.01 wt % to about 10 wt %, about 0.03 wt % to about 10 wt %, about 0.05 wt % to about 10 wt %, or about 0.08 wt % to about 10 wt %. In some embodiments, the corrosion inhibitor is present in an amount of greater than or equal to about 0.001 wt %, greater than or equal to about 0.005 wt %, greater than or equal to about 0.01 wt %, greater than or equal to about 0.03 wt %, greater than or equal to about 0.05 wt %, or greater than or equal to about 0.08 wt %. In some embodiments, the corrosion inhibitor is present in an amount of less than or equal to about 10 wt %, less than or equal to about 8 wt %, less than or equal to about 6 wt %, or less than or equal to about 5 wt %. In some embodiments, the oxidizing agent is present in an amount of about 0.001 wt %, about 0.005 wt %, about 0.01 wt %, about 0.05 wt %, about 0.08 wt %, or about 0.1 wt %.

The percentage of corrosion inhibitor is measured relative to the total composition. Additionally, the percentage of corrosion inhibitor is measured as the point of use (POU) composition. As used herein, the term “point of use” refers to a composition prepared and used in the vicinity of a planarization device that supplies planarization fluid to the individual planarization devices for use in the CMP process.

### Oxidizing Agent

The oxidizing agent is peroxide. Non-limiting examples of the oxidizing agent may include periodic acid, hydrogen peroxide, potassium iodate, potassium permanganate, persulfate (e.g., ammonium persulfate and potassium dipersulfate), periodate (e.g., perpotassium iodate), ammonium molybdate, ferric nitrate, nitric acid, potassium nitrate, and a mixture thereof. In some embodiments, the oxidizing agent is hydrogen peroxide.

In some embodiments, an amount of oxidizing agent affects the properties of the polishing composition, such as Mo removal rate (RR) and Mo etch rate (Mo ER). As discussed herein, oxidizing agents also affect the corrosion of Mo. An amount of oxidizing agent can vary in the range of about 0.01 wt % to about 5 wt %, about 0.01 wt % to about 3 wt %, or about 0.1 wt % to about 3 wt %. In some embodiments, the oxidizing agent is present in an amount of greater than or equal to about 0.01 wt %, greater than or equal to about 0.02 wt %, greater than or equal to about 0.03 wt %, greater than or equal to about 0.04 wt %, greater than or equal to about 0.05 wt %, or greater than or equal to about 0.1 wt %. In some embodiments, the oxidizing agent is present in an amount of less than or equal to about 5 wt %, or less than or equal to about 3 wt %.

The percentage of oxidizing agent is measured relative to the total composition. Additionally, the percentage of oxidizing agent is measured as the point of use (POU) composition. As used herein, the term “point of use” refers to a composition prepared and used in the vicinity of a planarization device that supplies planarization fluid to the individual planarization devices for use in the CMP process.

### Abrasive Particles

The abrasive particles may be composed of metal oxide. In some embodiments, the metal oxide may be composed of at least one material selected from silica, ceria, zirconia, alumina, titania, barium titania, tyrconia, germania, mangania, and magnesia. In some embodiments, the metal oxide may be a metal oxide coated with an organic or inorganic material, or a colloidal metal oxide. The abrasive particles may have a spherical shape, a modified spherical shape (cocoon type, rough spherical shape), a square shape, a needle shape, or a plate shape.

The abrasive particles may have an average particle diameter of about 10 nm (nanometer) to about 100 nm. When the average particle diameter of the abrasive particles is less than about 10 nm, the polishing rate of the film to be polished may decrease. If the average particle diameter of the abrasive particles exceeds about 100 nm, it may be disadvantageous in terms of suppressing surface defects on the surface to be polished and controlling the polishing rate.

The abrasive particles may be included in an amount of greater than about 0 wt % and less than about 15 wt % based on a total weight of the slurry composition. In one example, the abrasive particles may be included in an amount of about 0.01 wt % to about 20 wt % based on a total weight of the slurry composition. The slurry composition according to the technical idea of the present invention can exhibit excellent polishing performance on the film to be polished even when it contains a relatively small amount of abrasive particles.

In some embodiments, the amount of abrasive particles may vary in the range of about 0.01 wt % to about 20 wt %, about 0.05 wt % to about 20 wt %, or about 0.1 wt % to about 20 wt % based on a total amount of the slurry composition for chemical mechanical metal polishing. In some embodiments, the abrasive particles are present in an amount of greater than or equal to about 0.01 wt %, greater than or equal to about 0.02 wt %, greater than or equal to about 0.03 wt %, greater than or equal to about 0.04 wt %, greater than or equal to about 0.05 wt %, or greater than or equal to about 0.1 wt %. In some embodiments, the abrasive particles are present in an amount of less than or equal to about 20 wt %, or less than or equal to about 15 wt %.

The abrasive particles according to some embodiments may be a single material; or alternatively, a mixture of two types with different average particle diameters.

For example, the abrasive particles may be a single material of first abrasive particles.

For example, the abrasive particles may be a mixture of first abrasive particles and second abrasive particles.

In the case of a mixture of first abrasive particles and second abrasive particles, an average particle diameter ratio of the first abrasive particles and the second abrasive particles may be about 1:2.5 to about 1:10.

Specifically, the average particle diameter of the first abrasive particles may be about 10 nm to about 40 nm, and the average particle diameter of the second abrasive particles may be about 25 nm to about 100 nm.

In some embodiments, the average particle diameter of the first abrasive particles may be greater than or equal to about 10 nm and less than about 30 nm, about 15 nm to about 30 nm, or about 20 nm to about 30 nm.

In some embodiments, the average particle diameter of the second abrasive particles may be about 30 nm to about 80 nm, about 40 nm to about 60 nm, or about 45 nm to about 60 nm.

In some embodiments, the average particle diameter of the first abrasive particles may be about 10 nm, about 15 nm, about 20 nm, about 25 nm, or about 35 nm.

In some embodiments, the average particle diameter of the second abrasive particles may be about 40 nm, about 45 nm, or about 50 nm.

The first abrasive particles and the second abrasive particles may be included in a weight ratio of about 1:1 to about 10:1.

In some embodiments, the first abrasive particles and the second abrasive particles may be included in a weight ratio of about 1:1 to about 9:1, or about 1:1 to about 8:1.

In some embodiments, the first abrasive particles and the second abrasive particles can be included in a weight ratio of about 2:1, about 2.5:1, about 3:1, about 4:1, or about 5:1.

When two types of abrasive particles with different average particle sizes are mixed and used together with the aforementioned corrosion inhibitor, in addition to reducing Mo etching and improving Mo RR (removal rate), the SiN stopping function, which stops polishing for the silicon nitride-containing layer, can be improved.

In some embodiments, the abrasive particles may be surface-treated. For example, the surface-treated abrasive particles can be cationically modified silica. In one embodiment, the cationically modified silica may be silica that has been surface modified by treatment with an aminosilane to produce silica with a positive zeta potential. In another embodiment, the surface of the silica particles is treated with bis(trimethoxysilylpropyl)amine, an aminosilane such as SILQEST AI 170 (Crompton OSi Specialties), or a similar reactive aminosilane. Through these treatments, amino groups are covalently bonded to the surface of the cation-modified silica.

As an example, the aminosilane may be 3-aminopropyltriethoxysilane, 3-aminopropyltrimethoxysilane, 2-aminoethyl-3-aminopropyltrimethoxysilane, N-3-trimethoxysilylpropylbutan-1-amine, 2-aminoethyl-3-aminopropyltriethoxysilane, N-2-aminoethyl-3-aminopropyltriethoxysilane, etc.

Additionally, commercially available aqueous dispersions can be used, and examples of such commercial products may include Snowtex AK and Snowtex AK-L (both trade names manufactured by Nissan Kagaku Co., Ltd.), and Cataloid SN (Nissan Chemicals Co., Ltd.), and Quartron PL-3-C (trade name manufactured by Fuso Chemical High School Co., Ltd.).

When surface-treated abrasive particles are used with the corrosion inhibitor described above, in addition to reducing Mo etching, improving the Mo removal rate (RR), and improving the SiN stop function, which stops polishing against the silicon nitride-containing layer, a selectivity ratio for the removal rate of the silicon nitride-containing layer can be increased.

### Solvent

The solvent may be any liquid capable of substantially uniformly dispersing the oxidizing agent and/or abrasive, and is not particularly limited. The carrier may be an aqueous solvent or an organic solvent, but as described above, an aqueous solvent may be desirable.

In some embodiments, the solvent may include water, deionized water, ultrapure water, alcohol (e.g., propenyl alcohol, isopropyl alcohol, ethanol, 1-propanol, methanol, 1-hexanol, etc.), aldehyde (e.g., formaldehyde, acetaldehyde, etc.), ester (e.g. ethyl formate, propyl formate, ethyl acetate, methyl acetate, methyl lactate, butyl lactate, ethyl lactate, etc.), ketone (e.g. acetone, diacetone alcohol, methyl ethyl ketone, etc.), dimethyl sulfoxide (DMSO), tetrahydrofuran, dioxane, diglyme, amide (e.g., N,N-dimethyl formamide, dimethylimidazolidinone, N-methylpyrrolidone, etc.), polyhydric alcohol and a derivative thereof (e.g., ethylene glycol, glycerol, diethylene glycol, diethylene glycol monomethylether, etc.), a nitrogen-containing organic compound (e.g., acetonitrile, amylamine, isopropylamine, imidazole, dimethylamine, etc.), or a mixture thereof.

An amount of the solvent may be the remainder excluding the corrosion inhibitor, oxidizing agent, abrasive particles, and other components described later.

### Dispersion Stabilizer

The slurry composition for chemical mechanical metal polishing according to one aspect may or may not include a dispersion stabilizer. When the slurry composition for chemical mechanical metal polishing according to one aspect includes abrasive particles, it may include a dispersion stabilizer, and when it does not contain abrasive particles, a dispersion stabilizer that is generally added to ensure good dispersion of the abrasive particles may be unnecessary.

For example, the dispersion stabilizer may include at least one of ethylene oxide, ethylene glycol, glycol distearate, glycol monostearate, glycol polymerate, glycol ethers, alcohols containing alkylamines, compounds containing polymerate ether, vinyl pyrrolidone, celluloses, and ethoxylates. Specifically, the slurry composition for CMP includes at least one of diethylene glycol hexadecyl ether, decaethylene glycol hexadecyl ether, diethylene glycol octadecyl ether, eicosaethylene glycol octadecyl ether, diethylene glycol oleyl ether, decaethylene glycol oleyl ether, decaethylene glycol octadecyl ether, nonylphenol polyethylene glycol ether, ethylenediamine tetrakis(ethoxylate-block-propoxylate) tetrol, ethylenediamine tetrakis(propoxyl) ethylenediamine tetrakis(propoxylate-block-ethoxylate) tetrol, polyethylene-block-poly(ethylene glycol), polyoxyethylene isooctylphenyl ether, polyoxyethylene octylphenyl ether, polyoxyethylene tridecyl ether, polyoxyethylene sorbitan tetraoleate, polyoxyethylene sorbitol hexaoleate, polyethylene glycol sorbitan monolaurate, polyoxyethylene sorbitan monolaurate, sorbitan monopalmitate, FS-300 nonionic fluorosurfactant, FSN nonionic fluorosurfactant, FSO nonionic ethoxylated fluorosurfactant, vinyl pyrrolidone, 2,4,7,9-tetramethyl-5-decyne-4,7-diol ethoxylate, 8-methyl-1-nonanol propoxylate-block-ethoxylate, allyl alcohol 1,2-butoxylate-block-ethoxylate, polyoxyethylene branched nonylcyclohexyl ether, and polyoxyethylene isooctylcyclohexyl ether.

### pH Controlling Agent

For example, the pH of the slurry composition for chemical mechanical metal polishing can be achieved or maintained by any suitable means considering the polishing rate, dispersion stability, etc. As an example, the pH of the slurry composition for chemical mechanical metal polishing may be, for example, about 2 to about 6, and within the above range, about 3 to about 6, or about 3 to about 5. The pH controlling agent may be an acid. The acid is not particularly limited as long as the acid strength is sufficient to lower the pH of the polishing slurry composition of the present disclosure. For example, the acid may include hydrochloric acid, sulfuric acid, nitric acid, boric acid, carbonic acid, hypophosphorous acid, phosphorous acid, and phosphoric acid, but is not limited thereto.

The pH controlling agent may be present in a specific concentration range, regardless of pH.

### Surfactant

The slurry composition for chemical mechanical metal polishing may further include a surfactant if necessary. As the surfactant, an appropriate one may be selected and used among a nonionic surfactant, a cationic surfactant, an anionic surfactant, and an amphoteric surfactant.

The nonionic surfactant may include polyoxyethylene alkyl ethers such as polyoxyethylene lauryl ether and polyoxyethylene stearyl ether; polyoxyethylene alkyl phenyl ethers such as polyoxyethylene octylphenyl ether and polyoxyethylene nonylphenyl ether; sorbitan higher fatty acid esters such as sorbitan monolaurate, sorbitan monostearate, and sorbitan trioleate; polyoxyethylene sorbitan higher fatty acid esters such as polyoxyethylene sorbitan monolaurate; polyoxyethylene higher fatty acid esters such as oxyethylene monolaurate and polyoxyethylene monostearate; for example glycerol higher fatty acid esters such as oleic acid monoglyceride and stearic acid monoglyceride; polyoxyalkylenes such as polyoxyethylene, polyoxypropylene, and polyoxybutylene; and a block copolymer thereof.

Examples of the cationic surfactant may include alkyltrimethylammonium chloride, dialkyldimethylammonium chloride, a benzalkonium chloride salt, and alkyldimethylammonium ethosulfate.

Examples of the anionic surfactant may include a carboxylate salt such as sodium laurate, sodium oleate, sodium N-acyl-N-methylglycine, sodium polyoxyethylene lauryl ether carboxylate; a sulfonate salt such as sodium dodecylbenzenesulfonate, a dialkyl sulfosuccinic acid ester salt, and sodium dimethyl-5-sulfoisophthalate; a sulfuric acid ester salt such as sodium lauryl sulfate, sodium polyoxyethylene lauryl ether sulfate, and sodium polyoxyethylene nonylphenyl ether sulfate; and a phosphoric acid ester salt such as sodium polyoxyethylene lauryl phosphate and polyoxyethylene nonylphenyl ether sodium phosphate.

Examples of the amphoteric surfactant may include carboxybetaine type surfactant, aminocarboxylate, imidazolinium fetaine, lecithin, and alkylamine oxide.

The surfactant may be included in the slurry composition for metal CMP in an amount of about 0.001 wt % to about 0.5 wt %.

### Leveling Agent

The slurry composition for chemical mechanical metal polishing may, if necessary, further include a leveling agent that reduces irregularities of the surface to be polished.

Non-limiting examples of the leveling agent may include ammonium chloride, ammonium lauryl sulfate, polyethylene glycol, polyoxyethylene alkyl ether triethanolamine sulfate, polyvinylpyrrolidone, polyacrolein, etc.

The leveling agent may be included in a weight of about 0.1 wt % to about 1 wt % in the slurry composition for chemical mechanical metal polishing.

### Stabilizer

The slurry composition for chemical mechanical metal polishing may further include a stabilizer that prevents rapid decomposition of the oxidizing agent and maintains the slurry stably during polishing.

For example, the metal slurry composition for chemical mechanical metal polishing can be used to polish a conductive layer, an insulation layer and/or a semiconductor layer with charged surfaces in a semiconductor substrate. For example, the metal slurry composition for chemical mechanical metal polishing can be effectively used to polish conductive layers, insulating layers, and/or semiconductor layers that generally have negatively charged surfaces.

For example, the slurry composition for chemical mechanical metal polishing can be used to polish conductors such as a metal line in a semiconductor substrate, for example, to polish conductors such as molybdenum (Mo) and tungsten (W)/or alloys thereof.

Hereinafter, an example of a polishing method using the aforementioned chemical and mechanical metal polishing composition will be described.

A polishing method according to some embodiments includes arranging a substrate including a layer including at least one of molybdenum (Mo), tungsten (W), and an alloy thereof and a polishing pad to face each other; supplying the aforementioned slurry composition for chemical mechanical metal polishing between the substrate and the polishing pad; and performing polishing by bringing the surface of the substrate into contact with the polishing pad.

The layer including at least one of molybdenum (Mo), tungsten (W), and an alloy thereof includes an upper portion composed of molybdenum (Mo), tungsten, and/or an alloy thereof, and/or a lower portion including silicon oxide and molybdenum (Mo), tungsten, and/or an alloy thereof.

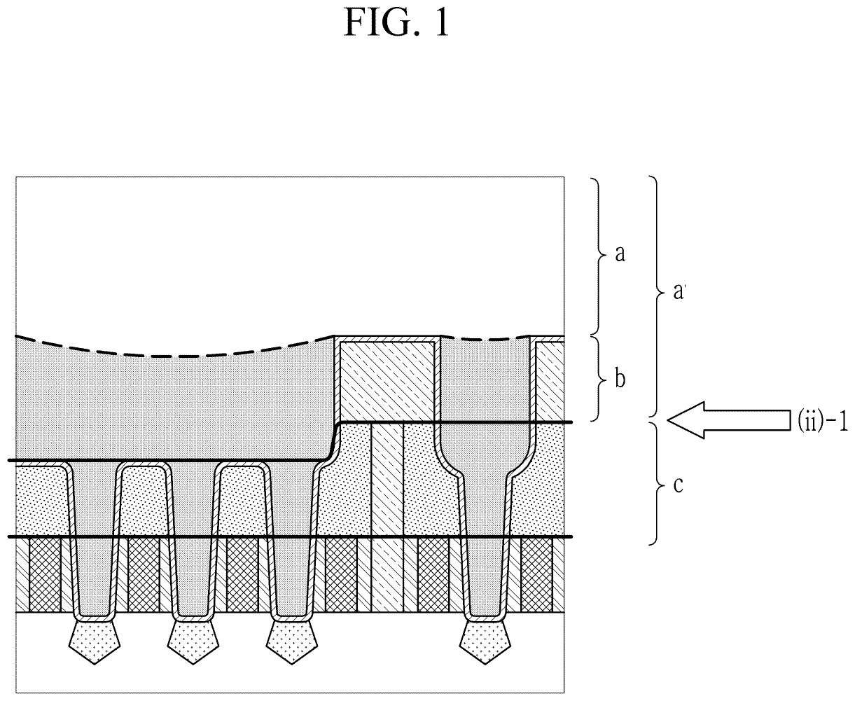

FIG. 1 is a diagram showing that, unlike the conventional polishing method, the polishing method according to one aspect can be implemented in a process shortened to 2 steps.

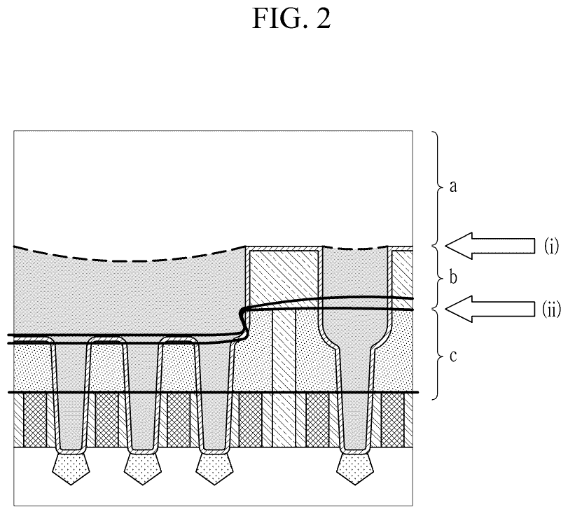

Referring to FIG. 1, the polishing method according to the present disclosure is a total of two steps of polishing process in which the upper portion (a) is polished and the lower portion (b) is continuously polished without stopping (a′: first step polishing), and after stopping at the point ((ii)-1) where the silicon nitride-containing layer begins, the silicon nitride-containing layer (c) is polished (second step polishing). FIG. 2 is a diagram showing that the conventional polishing method proceeds through a 3-step process.

Referring to FIG. 2, the conventional polishing method is a total of 3-step polishing process in which the upper portion (a) is polished (first step polishing), after stopping at the point where the lower portion begins ((i)), the lower portion (b) is polished (second step polishing), and the silicon nitride-containing layer (c) is polished (third step polishing) after stopping at the point where the silicon nitride-containing layer begins (ii).

According to FIGS. 1 and 2, in order to prevent the surface of a metal oxide, for example, molybdenum oxide, from being corroded by chemical etching, unlike the conventional polishing method in which the upper portion polishing and the lower portion polishing are carried out in two steps, in the polishing method according to the present invention, as the surface of the metal oxide, for example, molybdenum oxide, is protected by a corrosion inhibitor, chemical etching is suppressed and melting can be prevented, so that polishing of the upper and lower portions can be performed continuously without stopping which makes it possible to shorten the process.

The polishing of the upper portion may be performed at about 40° C. to about 60° C., and the polishing of the lower portion may be performed at about 20° C. to about 40° C.

A thickness of the upper portion may be about 100 Å to about 3,000 Å.

A thickness of the lower portion may be about 0 Å to about 200 Å.

The temperature control may be performed through a temperature control unit of the polishing device. Specifically, the temperature control unit may include at least one of an injector that sprays gas onto the polishing surface and a heat exchanger in which a fluid flows.

In some embodiments, the temperature of the polishing surface can be controlled by spraying gas from an injector.

Recess defects can be improved by polishing the lower portion at a lower temperature than when polishing the upper portion.

The substrate further includes a silicon nitride-containing layer, and a selectivity ratio of a removal rate of the layer including at least one of molybdenum (Mo), tungsten (W), and an alloy thereof to a removal rate of the silicon nitride-containing layer may be greater than or equal to about 7:1.

In some embodiments, the selectivity ratio may be greater than or equal to about 8:1, greater than or equal to about 9:1, greater than or equal to about 10:1, greater than or equal to about 15:1, greater than or equal to about 17:1, greater than or equal to about 20:1, or greater than or equal to about 30:1. The upper limit of the selectivity ratio is not particularly limited, but in practice it may be about 50:1, about 100:1, about 200:1, about 300:1, about 400:1, about 500:1, about 600:1, about 700:1, about 800:1, about 900:1, or about 1000:1 or less.

As mentioned above, although example embodiments have been described, various additions, omissions, substitutions, and changes may be made without being limited to the example embodiments described above. Further, it is possible to form other embodiments by combining elements in different embodiments.

Hereinafter, the configuration and effects of the present invention will be described in more detail with specific examples and comparative examples, but these examples are only intended to more clearly understand the present invention and are not intended to limit the scope of the present invention.

### (Preparation of Slurry Composition for Chemical Mechanical Metal Polishing)

### Examples 1 to 3

A slurry composition for chemical mechanical metal polishing was prepared by mixing hydrogen peroxide as an oxidizing agent, silica particles A1 (average particle diameter: 20 nm) as abrasive particles, and a corrosion inhibitor in deionized water (A) in the composition shown in Table 1. The amount of each component refers to weight percent based on the total weight (100 wt %) of the slurry.

### Comparative Example 1

A slurry composition for chemical mechanical metal polishing was prepared by mixing the composition shown in Table 1 without a corrosion inhibitor.

### Comparative Examples 2 and 3

A slurry composition for chemical mechanical metal polishing was prepared by changing the abrasive particles to silica particles A2 (average particle diameter: 80 nm) and mixing them with the composition shown in Table 1.

### Comparative Example 4

A slurry composition for chemical mechanical metal polishing was prepared by changing the average particles to alpha-alumina (A3, average particle diameter: 120 nm) and mixing them with the composition shown in Table 1.

### Comparative Examples 5 to 10

A slurry composition for chemical mechanical metal polishing was prepared by changing the corrosion inhibitor to the composition shown in Table 1.

### Examples 4 to 10

A slurry composition for chemical mechanical metal polishing was prepared by using 1 wt % of hydrogen peroxide as an oxidizing agent, changing the abrasive particles to a mixture of first silica particles with an average particle diameter of 25 nm and second silica particles with an average particle diameter of 50 nm, and mixing to the composition shown in Table 3.

The pH of the slurry compositions was all 4.

The compositions of Examples 4 to 10 are as shown in Table 3.

### Example 11

A slurry composition for chemical mechanical metal polishing was prepared by using 3 wt % of hydrogen peroxide as an oxidizing agent and mixing 0.5 wt % of silica (average particle diameter: 50 nm) surface-treated with 0.015 wt % of 3-aminopropyltriethoxysilane.

The pH of the slurry compositions was 4.

### Example 12

A slurry composition for chemical mechanical metal polishing was prepared in the same manner as in Example 11, except that silica (average particle diameter: 50 nm) surface-treated with 0.03 wt % of 3-aminopropyltriethoxysilane was used.

The pH of the slurry composition was 4.

The compositions of Examples 1 to 3 and Comparative Examples 1 to 10 are as shown in Table 1.

TABLE 1

| | Abrasive particles | | | | Oxidizing | | | | | | |
|---|---|---|---|---|---|---|---|---|---|---|---|
| | (wt %) | | | | agent | Corrosion inhibitor (wt %) | | | | | |
| | A1 | A2 | A3 | pH | (wt %) | C1 | C2 | C3 | C4 | C5 | C6 |
| Ex. 1 | 1 | | | 4 | 3 | | | | | 0.005 | |
| Ex. 2 | 1 | | | 4.3 | 3 | | | | | 0.005 | |
| Ex. 3 | 1 | | | 4.3 | 3 | | | | | | 0.005 |
| Comp. | 1 | — | — | 3 | 3 | — | — | — | — | — | — |
| Ex. 1 | | | | | | | | | | | |
| Comp. | — | 3 | — | 3 | 0.5 | 0.01 | — | — | 0.005 | — | — |
| Ex. 2 | | | | | | | | | | | |
| Comp. | — | 3 | — | 3 | 0.5 | — | 0.01 | — | 0.005 | — | — |
| Ex. 3 | | | | | | | | | | | |
| Comp. | — | — | 1.5 | 3 | 0.5 | — | — | 0.01 | 0.005 | — | — |
| Ex. 4 | | | | | | | | | | | |
| | | | | | Oxidizing | | | | | | |
| | | | | | agent | | | | | | |
| | A1 | A2 | A3 | pH | (wt %) | C7 | C8 | C9 | C10 | C11 | C12 |
| Comp. | 1 | — | — | 3 | 1 | 0.005 | | | | | |
| Ex. 5 | | | | | | | | | | | |
| Comp. | 1 | | | 3 | 1 | | 0.005 | | | | |
| Ex. 6 | | | | | | | | | | | |
| Comp. | 1 | | | 3 | 1 | | | 0.005 | | | |
| Ex. 7 | | | | | | | | | | | |
| Comp. | 1 | | | 3 | 1 | | | | 0.005 | | |
| Ex. 8 | | | | | | | | | | | |
| Comp. | 1 | | | 3 | 1 | | | | | 0.005 | |
| Ex. 9 | | | | | | | | | | | |
| Comp. | 1 | | | 3 | 1 | | | | | | 0.005 |
| Ex. 10 | | | | | | | | | | | |

Abrasive particles
A1: silica particle (average particle diameter: 20 nm)
A2: silica particle (average particle diameter: 80 nm)
A3: alpha-alumina (average particle diameter: 120 nm)
Corrosion inhibitor
C1: Polydiallyldimethylammonium chloride (polyDADMAC)
C2: cetyltrimethylammonium bromide (CTAB)
C3: PolyMADQUAT
C4: 1,2,4-triazole
C5: 1-Dodecylpyridinium chloride
C6: 1-Dodecyl-1H-imidazole
C7: 4-mercaptopyridine
C8: Benzenesulfonic acid
C9: Benzothiazole
C10: Phytic acid
C11: Aminotriazole
C12: Tetrazole
(Evaluation Methods)
<Polishing condition>
Polishing device: ALLIED precision polishing device MultiPrep system (Allied High Tech Products, Inc.)
Polishing platen rotation speed: 200 rpm
Head rotation speed: 60 pm
Flow rate: 15 mL/min
Down force: 1.5 psi
Polishing time: 60 seconds
Pad: Vision Pad 6000 manufactured by Dupont
Dilution factor: 6 times
<Conditions of static etch rate>
for 1 minute at 25° C.
Mo test piece: 2 kA Mo wafer (manufactured by Advantiv) (a molybdenum film formed with a thickness of 2000 Å on a Si substrate of 1.5 inches length × 1.5 inches width × about 780 μm thickness).

### [Polishing Experiment]

Using the slurries according to Examples 1 to 12 and Comparative Examples 1 to 10, the following TEOS substrates and Mo substrates were polished according to the polishing conditions.
TEOS substrate: 10 KA TEOS wafer (manufactured by Advantiv) (TEOS film formed with a thickness of 10000 Å on a Si substrate of 1.5 inches length×1.5 inches width×about 780 μm thickness).
Mo substrate: 2 kA Mo wafer (manufactured by Advantiv) (a molybdenum layer formed with a thickness of 2000 Å on a Si substrate of 1.5 inches length×1.5 inches width×about 780 μm thickness).

### [Polishing Rate]

The polishing rate is calculated by measuring the average of the film thickness values of 17 points in the plane of each substrate before and after polishing using CMT-Series (AIT Co., Ltd.) to calculate the polished film thickness (Å) and calculating the polished film thickness (A) as the polishing time (minutes).

### [Static Etch Rate]

Using the slurries according to Examples 1 to 12 and Comparative Examples 1 to 10, etching was performed using a Mo specimen according to the above static etch rate conditions. The static etch rate is calculated by measuring the film thickness before and after etching using CMT-Series (AIT Co., Ltd), and the etched film thickness (Å) is calculated as the etching time (minutes).

### [SiN Polishing Stop Loss]

After completing polishing of the upper molybdenum layer and the lower molybdenum layer, the reduced thickness of the silicon nitride-containing layer was confirmed using an optical thickness gauge (ST-2000, K-MAC).

TABLE 2

| | Mo removal rate | Mo etch rate |
|---|---|---|
| | (R/R) Å/min | (E/R) Å/min |
| Ex. 1 | 985 | 14 |
| Ex. 2 | 1011 | 11 |
| Ex. 3 | 1051 | 13 |
| Comp. Ex. 1 | 1362 | 617 |
| Comp. Ex. 2 | 460 | 488 |
| Comp. Ex. 3 | 492 | 372 |
| Comp. Ex. 4 | 608 | 515 |
| Comp. Ex. 5 | — | 150 |
| Comp. Ex. 6 | — | 134 |
| Comp. Ex. 7 | — | 101 |
| Comp. Ex. 8 | — | 188 |
| Comp. Ex. 9 | — | 191 |
| Comp. Ex. 10 | — | 141 |

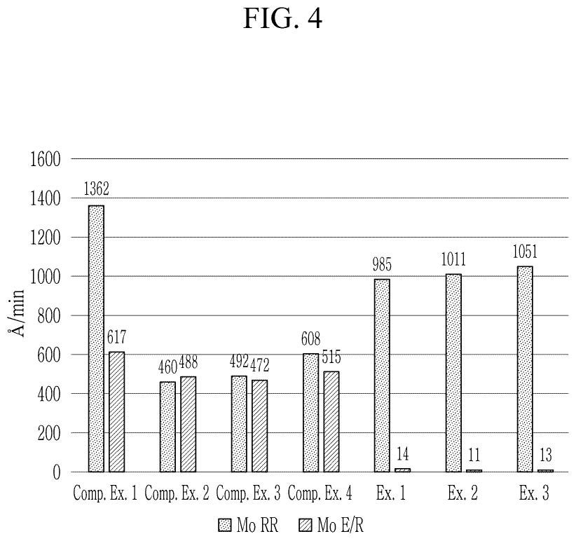

FIG. 4 is a graph showing molybdenum removal rate and corrosion rate (etch rate) by chemical etching.

Referring to Table 2 and FIG. 4, the use of the corrosion inhibitor according to the present invention increased the Mo polishing rate and reduced the Mo etch rate.

TABLE 3

Abrasive particles

| | first | second | | |
|---|---|---|---|---|
| | abrasive | abrasive | Mo removal | SiN stop |
| | particles | particle | rate (R/R) | loss |
| | (wt %) | (wt %) | Å/min | (nm) |
| Ex. 4 | 0.75 | 0.1 | 1244 | 33 |
| Ex. 5 | 0.5 | 0.1 | 1200 | 29 |
| Ex. 6 | 0.25 | 0.1 | 1146 | 31 |
| Ex. 6 | 0.25 | 0.3 | 1308 | 39 |
| Ex. 7 | 0.75 | 0.05 | 1052 | 21 |
| Ex. 8 | 0.5 | 0.05 | 872 | 18 |
| Ex. 9 | 0.25 | 0.05 | 829 | 16 |
| Ex. 10 | 0.12 | 0.05 | 887 | 19 |

Referring to Table 3, when two types of abrasive particles with different average particle diameters are mixed, the Mo polishing rate is increased while the SiN loss is reduced, and this shows that the SiN stopping function is excellent.

TABLE 4

| | Mo removal | | Selectivity of Mo |
|---|---|---|---|
| | rate | SiN stop loss | removal rate to SiN |
| | (R/R) Å/min | (nm) | removal rate |
| Ex. 11 | 1295 | 7.5 | 17.3 |
| Ex. 12 | 1341 | 18 | 7.5 |

The selectivity ratio of the Mo removal rate to the SiN removal rate was calculated as the Mo removal rate relative to the SiN stop loss thickness.

Referring to Table 4, when using abrasive particles surface-treated with aminosilane, the Mo polishing rate is increased while the SiN loss is reduced, and in particular, the selectivity of the Mo removal rate to the SiN removal rate is improved.

While this disclosure has been described in connection with what is presently considered to be practical exemplary embodiments, it is to be understood that the invention is not limited to the disclosed embodiments, but, on the contrary, is intended to cover various modifications and equivalent arrangements included within the scope of the appended claims.

### DESCRIPTION OF SYMBOLS

20: polishing table
30: top ring
31: shaft
34: support arm
40: polishing liquid supply nozzle
42: shaft
50: polishing liquid removal unit
60: temperature control unit
100: polishing pad
102: polishing surface
Wk: substrate

What is claimed is:

1. A slurry composition for chemical mechanical metal polishing, the slurry composition comprising:
a corrosion inhibitor, abrasive particles, an oxidizing agent, and a solvent,
wherein the corrosion inhibitor comprises:
a C2 to C30 aliphatic heterocyclic compound comprising a ring having at least one nitrogen atom and at least one functional group selected from a halogen, an amine group, a cyclic amine group, a nitro group, an amide group, a carboxyl group, a hydroxy group, a thiol group, an alkoxy group, a C10 to C30 alkyl group, or an ester group; or
a C2 to C30 aromatic heterocyclic compound comprising a ring having at least one nitrogen atom and at least one functional group selected from a halogen, an amine group, a cyclic amine group, a nitro group, an amide group, a carboxyl group, a hydroxy group, a thiol group, an alkoxy group, a C10 to C30 alkyl group, or an ester group; or
a combination thereof.

2. The slurry composition of claim 1, wherein the corrosion inhibitor comprises one or more of the following:
diazepane including at least one functional group selected from a halogen, an amine group, a cyclic amine group, a nitro group, an amide group, a carboxyl group, a hydroxy group, a thiol group, an alkoxy group, a C10 to C30 alkyl group, or an ester group;
pyridine including at least one functional group selected from a halogen, an amine group, a cyclic amine group, a nitro group, an amide group, a carboxyl group, a hydroxy group, a thiol group, an alkoxy group, a C10 to C30 alkyl group, or an ester group;
pyridinium including at least one functional group selected from a halogen, an amine group, a cyclic amine group, a nitro group, an amide group, a carboxyl group, a hydroxy group, a thiol group, an alkoxy group, a C10 to C30 alkyl group, or an ester group;
imidazole including at least one functional group selected from a halogen, an amine group, a cyclic amine group, a nitro group, an amide group, a carboxyl group, a hydroxy group, a thiol group, an alkoxy group, a C10 to C30 alkyl group, or an ester group;
imidazolium including at least one functional group selected from a halogen, an amine group, a cyclic amine group, a nitro group, an amide group, a carboxyl group, a hydroxy group, a thiol group, an alkoxy group, a C10 to C30 alkyl group, or an ester group;
pyrazole including at least one functional group selected from a halogen, an amine group, a cyclic amine group, a nitro group, an amide group, a carboxyl group, a hydroxy group, a thiol group, an alkoxy group, a C10 to C30 alkyl group, or an ester group;
pyrazolium including at least one functional group selected from a halogen, an amine group, a cyclic amine group, a nitro group, an amide group, a carboxyl group, a hydroxy group, a thiol group, an alkoxy group, a C10 to C30 alkyl group, and an ester group.

3. The slurry composition of claim 1, wherein the corrosion inhibitor includes 11-undecyl-1,4-diazepane; 1-decyl-3-[(2S)-1-methyl-2-pyrrolidinyl] pyridinium iodide; 1-dodecylpyridinium chloride; 2-heptadecylimidazole; 1-dodecyl-1H-imidazole; 4-amino-1-dodecyl-pyridinium chloride; 1-heptyl-1H-imidazol-2-amine; 4-benzyl-1H-imidazol-2-amine; 4-chloro-1H-pyrazole-3-carboxylic acid; 5-Isopropyl-1H-pyrazol-3-amine; 4-Isopropyl-1H-pyrazol-3-amine; 1-decyl-3-methylimidazolium chloride; 3-decyl-1,2-dimethyl-1H-imidazol-3-ium bromide; or a combination thereof.

4. The slurry composition of claim 1, wherein the slurry composition has pH of about 2 to about 6.

5. The slurry composition of claim 1, wherein an average particle diameter of the abrasive particles is about 10 nm to about 100 nm.

6. The slurry composition of claim 1, wherein the abrasive particles comprise a single material or a mixture of two types of materials with different average particle diameters.

7. The slurry composition of claim 6, wherein
the abrasive particles comprise a single material of first abrasive particles or a mixture of the first abrasive particles and second abrasive particles, and
an average particle diameter ratio of the first abrasive particles and the second abrasive particles is about 1:2.5 to about 1:10.

8. The slurry composition of claim 7, wherein
the average particle diameter of the first abrasive particles is about 10 nm to about 40 nm, and
the average particle diameter of the second abrasive particles is about 25 nm to about 100 nm.

9. The slurry composition of claim 7, wherein a weight ratio of the first abrasive particles to the second abrasive particles is about 1:1 to about 10:1.

10. The slurry composition of claim 7, wherein a weight ratio of the first abrasive particles to the second abrasive particles is about 2:1 to about 6:1.

11. The slurry composition of claim 1, wherein the abrasive particles are surface-treated with amino silane.

12. The slurry composition of claim 1, wherein the oxidizing agent is present in an amount of about 0.01 to about 5 wt % of a total weight of the slurry composition.

13. The slurry composition of claim 1, wherein the corrosion inhibitor is present in an amount of about 0.001 to about 10 wt % of a total weight of the slurry composition.

14. The slurry composition of claim 1, wherein the abrasive particles are included in an amount of about 0.01 to about 20 wt % based on a total weight of the slurry composition.

15. A polishing method, comprising:
arranging a polishing pad to face a surface of a substrate, wherein the substrate comprises a layer that includes at least one of molybdenum (Mo), tungsten (W), or an alloy thereof;
supplying the slurry composition of claim 1 between the substrate and the polishing pad; and
polishing the substrate by bringing the surface of the substrate into contact with the polishing pad.

16. The method of claim 15, wherein
the layer comprises:
an upper portion comprising molybdenum (Mo), tungsten, and/or an alloy thereof, and
a lower portion comprising silicon oxide and molybdenum (Mo), tungsten, and/or an alloy thereof.

17. The method of claim 16, wherein the polishing the substrate comprises polishing the upper portion and then the lower portion continuously.

18. The method of claim 17, wherein
the polishing the upper portion is performed at about 40° C. to about 60° C., and
the polishing the lower portion is performed at about 20° C. to about 40° C.

19. The method of claim 16, wherein the substrate further comprises a silicon nitride-containing layer.

20. The method of claim 19, wherein a selectivity ratio of a removal rate of the layer to a removal rate of the silicon nitride-containing layer is greater than or equal to about 7:1.
